(19) United States
(12) Patent Application Publication
(10) Pub. No.: US 2002/0131257 A1
(43) Pub. Date: Sep. 19, 2002

(54) Detachable partition extension

(76) Inventor: Kenneth K. Agard, Rohnert Park, CA (US)

Correspondence Address: ALCATEL USA, INTELLECTUAL PROPERTY DEPARTMENT, 1000 COIT ROAD, MS LEGL2, PLANO, TX, 75075, US

(21) Appl. No.: 09/808,518

(22) Filed: Mar. 14, 2001

(51) Int. Cl. H05K 7/18

(52) U.S. Cl. 361/796

(57) ABSTRACT

A partition extension for compartmentalizing a shelf in order to accommodate line cards of different form factors. The partition extension, comprised of a substantially rigid material, is horizontally disposed relative to the shelf's backplane. An upper partition member and a lower partition member are coupled together and are removably attached to the backplane at a predetermined location depending on the form factor of the cards to be accommodated. In an exemplary embodiment of the present invention, the backplane is operable to support both full-height and half-height line cards.

### CROSS-REFERENCE TO RELATED APPLICATION(S)

This application discloses subject matter related to the subject matter disclosed in the following commonly owned co-pending patent application(s): (i) “Card Alignment Guide,” filed______ , Ser. No.:______ (Attorney Docket Number 1285-0051US), in the name(s) of: Kenneth K. Agard.

### BACKGROUND OF THE INVENTION

1. Technical Field of the Invention

The present invention generally relates to telecommunications equipment. More particularly, and not by way of any limitation, the present invention is directed to an extension for partitioning a card-carrying shelf into compartments that are capable of accommodating line cards of different sizes.

2. Description of Related Art

The exponential increase in the number of local telephone lines, mobile subscribers, pagers, fax machines, and other data devices, e.g., computers, information appliances, etc., coupled with deregulation that is occurring worldwide today is driving demand for high capacity telecommunications equipment which must be easy to maintain, provide “five nines” operational availability (i.e., 99.999% uptime), and support future functionality or features as the need arises. Further, as subscriber demand for more service options proliferates, an evolution is taking place in the telecommunications industry to integrate Intelligent Network (IN)-capable Service Control Point (SCP) functionality within other network nodes such as, e.g., Signal Transfer Points (STPs).

While it is generally expected that a single platform that supports large-database, high-transaction IN services as well as high-capacity packet switching (hereinafter referred to as a signaling server platform) will reduce equipment costs, reduce network facility costs and other associated costs while increasing economic efficiency, those skilled in the art should readily recognize that several difficulties must be overcome in order to integrate the requisite functionalities into a suitable network element that satisfies the stringent performance criteria required of telecommunications equipment. Daunting challenges arise in designing a compact enough form factor that is efficiently scalable, ruggedized, and modularized for easy maintenance, yet must house an extraordinary constellation of complex electronic circuitry, e.g., processors, control components, timing modules, I/O, line interface cards which couple to telephony networks, etc., that is typically required for achieving the necessary network element functionality. The electronic components may themselves be miniaturized and modularized into cards or boards that can be interconnected via suitable backplanes, accommodated by a chassis or shelf.

It should be apparent to those skilled in the art that the maintainability of different components in sophisticated equipment is a significant factor with respect to the equipment's availability and reliability in the field. Providing redundant components is a well known practice for achieving high availability with respect to complicated equipment such as, for example, network elements disposed in a telecommunications network. Typically, such equipment is compartmentalized into racks and shelves, each compartment having duplicate sets of components disposed on respective backplanes, wherein one set is active (carrying on the operation of the equipment) and the other set is provided as stand-by.

It should be further recognized by those skilled in the art that increased functionality and requirements to comply with the legacy infrastructure necessitate the use of line cards that have different sizes (such as full-height, half-height, quarter-height, and so on). The existing solutions for maintaining line cards with different sizes, however, require the deployment of shelves with different form factors, which results in a high degree of architectural customization in, for example, a telecommunications network. The end result is a highly inflexible and less modularizable system. Furthermore, since more components (i.e., shelves deploying multiple form factors) are required, customized maintenance must be undertaken for each shelf. Consequently, increased manufacturing costs in terms of both components and labor are incurred.

Additionally, network service providers employing line cards with multiple form factors are required to purchase a plurality of different shelves with different form factors. Thus, economies of scale advantages are frustrated because of the service provider's inability to make a bulk purchase of, and deploy, shelves that possess the same form factor.

As line cards with different sizes are continually being developed, it would therefore be advantageous to be able to accommodate these line cards on the same legacy backplane without having to design brand new equipment or backplanes with slots of different sizes. This would also allow for the gradual integration of newer form factor line cards with older line cards. Additionally, the deployment of shelves with a uniform form factor would allow for ease of maintenance and for economies of scale to be realized.

### SUMMARY OF THE INVENTION

Accordingly, the present invention advantageously provides one or more detachable partition extensions for compartmentalizing a shelf into modularizable chambers, wherein line cards of different sizes can be easily accommodated as the need therefor arises. The partition extension is comprised of a substantially rigid material such as metal, plastic, and so on. In a presently preferred exemplary embodiment of the present invention, the partition extension is comprised of an upper partition member and a lower partition member wherein both are horizontally disposed relative to a backplane of the shelf by coupling at a predetermined location thereon. Preferably, the partition members each incorporate a back flange for facilitating coupling with the backplane. A plurality of different coupling means such as screw fasteners, removal rivets, clips, buckles, clasps, clamps, braces, grips, bolts, locks, nails, pins, and so on may be utilized. Further, the partition extension may be coupled to the backplane at a plurality of different locations relative to the backplane such as the center, the lower one-third, the lower one-quarter, the upper one-third, the upper one-quarter, and so on. Moreover, several partition extensions may be simultaneously disposed on the same backplane at different locations. As a result, the interior space of the shelf can be rendered to be highly partitionable so as to accommodate line cards having a plurality of different form factors.

In the preferred exemplary embodiment of the present invention, the shelf is operable to accommodate a plurality of half-height line cards (e.g., legacy cards) by attaching a partition extension at the center of the backplane. When the partition extension is detached, the shelf or a portion thereof is operable to receive a plurality of full-height line cards. In a further aspect, the upper and lower partition members are provided with a plurality of card guides comprised of metal, plastic, and so on. In an exemplary embodiment of the present invention, the card guides can be arranged in rows of eight.

In a still further aspect, the shelf is able to support a plurality of partition extensions that are removably attachable to the backplane. When at least one partition extension is coupled to the backplane, both half-height and full-height line cards can be accommodated concurrently. Additionally, the partition extension can accommodate a form factor that would enable the shelf to receive line cards of different sizes simultaneously.

### BRIEF DESCRIPTION OF THE DRAWINGS

A more complete understanding of the present invention may be had by reference to the following Detailed Description when taken in conjunction with the accompanying drawings wherein:

FIG. 1 depicts a perspective view of an exemplary embodiment of the present invention, wherein a detachable partition extension is coupled to a backplane;

FIG. 2 depicts a perspective view of an exemplary upper partition member of the partition extension shown in FIG. 1;

FIG. 3 depicts a perspective view of an exemplary lower partition member of the partition extension shown in FIG. 1;

FIG. 4 depicts a side view of an exemplary embodiment of the present invention, wherein the detachable partition extension is attached to the backplane; and

FIG. 5 depicts a perspective view of an exemplary embodiment of the present invention, wherein two detachable partition extensions are accommodated within a shelf.

### DETAILED DESCRIPTION OF THE DRAWINGS

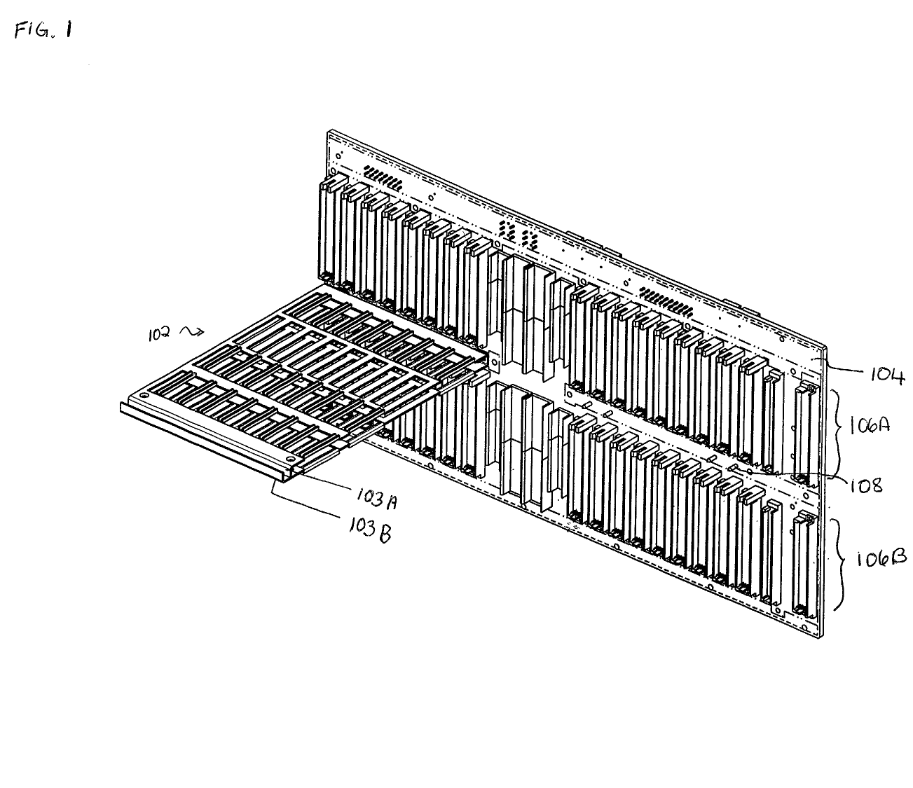

In the drawings, like or similar elements are designated with identical reference numerals throughout the several views thereof, and the various elements depicted are not necessarily drawn to scale. Referring now to FIG. 1, depicted therein is a perspective view of an exemplary embodiment of a detachable partition extension 102 coupled to a backplane 104 of a shelf provided in accordance with the teachings of the present invention. Preferably, the backplane 104 is located in the back of the shelf and is operable to support a plurality of card connector receptacles (e.g., 3-row or 5-row male pin connectors) which are used for connecting a plurality of line cards having corresponding female card connectors. Typically, the backplane itself may accommodate little circuitry.

Reference numerals 106A and 106B refer to two banks of card connector receptacles disposed on the back plane 104, which are operable to accommodate a plurality of different types of line cards such as Synchronous Optical Network (SONET) line cards, T1 line cards, Digital Subscriber Line (DSL) line cards, and so on. The cards themselves are provided with either one or two female connectors, depending on whether they are full-height or half-height cards. Accordingly, a full-height card is secured by inter-locking its two female connectors with the corresponding two vertically aligned male receptacles, one from each receptacle bank.

In the exemplary embodiment, depicted in FIG. 1, the partition extension 102 for compartmentalizing the shelf is comprised of an upper partition member 103A and a lower partition member 103B. The partition extension 102 can be constructed of any suitable rigid material such as steel, aluminum, plastic, and so on. Further, either or both partition members (reference numerals 103A and 103B, respectively) can accommodate a plurality of formed guides on their surfaces. The partition extension 102 is substantially horizontally attached to the backplane 104 in a detachable manner at a half-way point between the backplane's top and bottom so as to segregate an upper backplane position having receptacle bank 106A from a lower backplane portion housing receptacle bank 106B. Half-height line cards having only one female connector may therefore be advantageously accommodated on either the upper-half or the lower-half portion of the backplane by securing the detachable partition extension 102. Furthermore, where the backplane provides for coupling with multiple partition extensions aligned on a single plane, both full-height cards and half-height cards can coexist in the shelf by not employing at least one of the multiple partition extensions. In addition, it should be realized by those skilled in the art that a similar arrangement may be achieved by employing only one detachable partition extension which does not span the entire length of the backplane.

It should further be recognized that a variety of coupling mechanisms may be provided for securing the partition extension 102 to the backplane. For example, alignment pins 108 may be provided on the backplane 104 which can be inserted into corresponding holes on the upper and lower partition members (described in greater detail hereinbelow) of the partition extension. Other coupling means such as screw fasteners, removable rivets, clips, braces, bolts, locks, nails, etc., may also be advantageously utilized for attaching the partition extension members to the backplane in accordance with the teachings of the present invention.

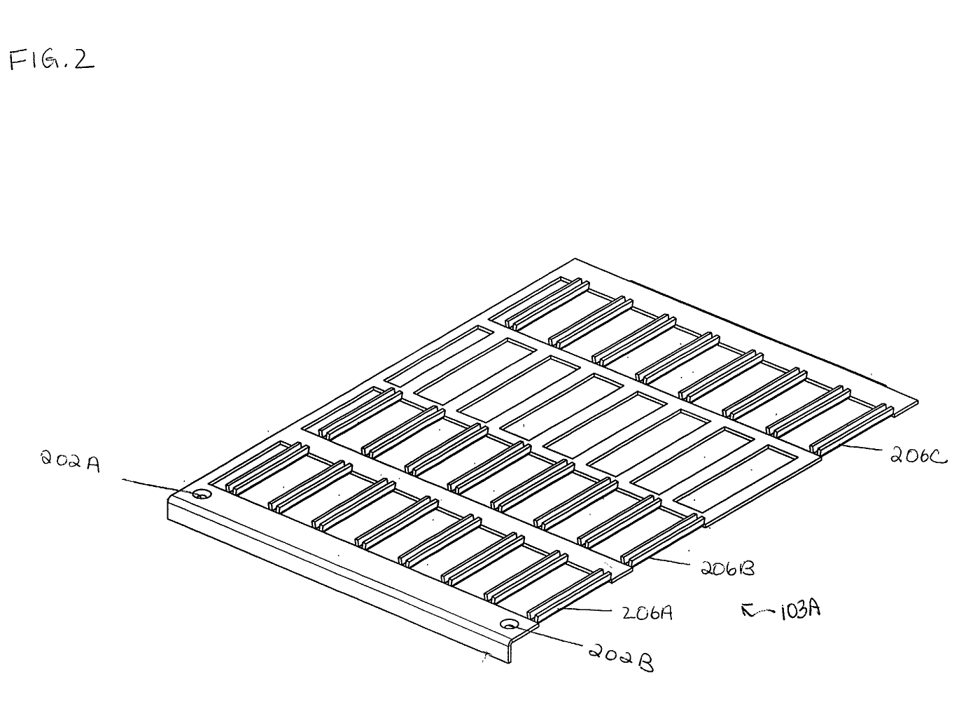

Referring now to FIG. 2, depicted therein is a perspective view of the exemplary upper partition member 103A of the present invention. As alluded to hereinabove, the upper partition member can accommodate a plurality of card guides (e.g., reference numerals 206A, 206B and 206C) on its upper surface. Each card guide (such as card guide 206A) can be comprised of a pair of raised projections which surround a slot located in the center of the card guide 206A. Each line card sits in the slots of a given column of card guides (such as a column of card guides comprising card guide portions 206A, 206B and 206C). The card guides provide support to the accommodated line cards, and thereby prevent card warpage. Each card guide (i.e., card guide 206A) can be formed from a plurality of materials, such as plastic, steel, aluminum, and so on. In a presently preferred exemplary embodiment of the present invention, the card guides can be arranged in rows of eight.

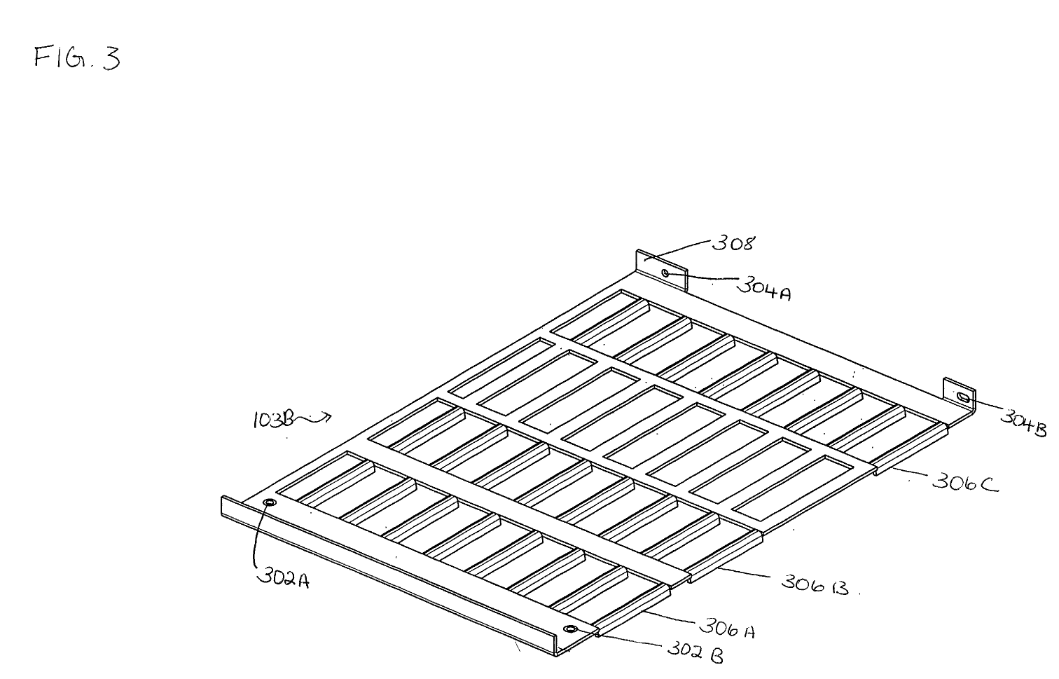

Continuing to refer to FIG. 2, the front section of the upper partition member 102A can accommodate a plurality of fastener clearance holes (such as clearance holes 202A and 202B). The clearance holes align with a corresponding plurality of self clinching threaded inserts located in the lower partition member (shown in FIG. 3). Although not shown, fasteners can be installed in the upper partition member clearance holes (i.e., reference numeral 202A and 202B) and attached to the threaded inserts of the lower partition member 103B for securing the upper and lower partition members together.

In the preferred embodiment of the present invention, a plurality of alignment holes are accommodated by a back flange (not explicitly shown) of the upper partition member 103A. The alignment holes mate with a plurality of alignment projections or pins located on the backplane 104 (such as projections 108 shown in FIG. 1) in order to couple the upper partition member 103A with the backplane 102, preferably in conjunction with the lower partition member 103B.

FIG. 3 depicts a perspective view of the lower partition member 103B of the present invention. The lower partition member can accommodate a plurality of card guides on its lower surface (reference numerals 306A, 306B and 306C). As has been described hereinabove, each card guide (such as card guide 306A) may be comprised of a plurality of different materials and accommodates a central groove or slot on which a line card can sit. Each line card resides in the grooves of a given column of card guides (such as card guide column 306A, 306B and 306C). Similar to the card guide arrangement of the upper partition member described hereinabove, the card guides of the lower partition member can be arranged in rows of eight.

As has been pointed out heretofore, the front section of the lower partition member 103B can accommodate a plurality of self clinching threaded inserts (i.e., reference numerals 302A and 302B) that align with the clearance holes of the upper partition member 103A. Although not shown, in order to couple the lower partition member 103B to the upper partition member 103A, fasteners can be installed in the upper partition member clearance holes (such as clearance holes 202A and 202B shown in FIG. 2) and attached to the corresponding lower partition member threaded inserts (such as threaded inserts 302A and 302B).

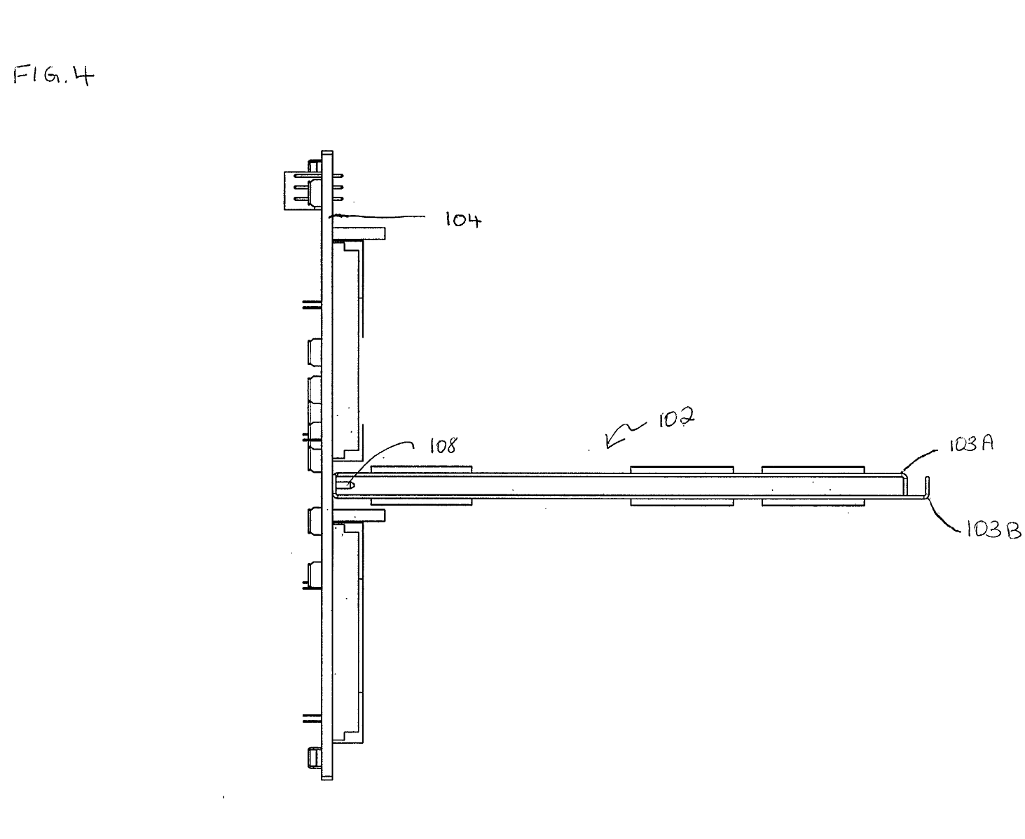

The lower partition member 103B is provided with a back flange 308 which can accommodate a plurality of alignment holes (i.e., reference numerals 304A and 304B). The alignment holes mate with the alignment projections located on the backplane in order to couple the upper and lower partition members 103A, 103B with the backplane 104 (shown in greater detail in FIG. 4).

FIG. 4 depicts a side view of an exemplary embodiment of the present invention, wherein the upper partition member 103A and the lower partition member 103B are coupled to the backplane 104. As has been described hereinabove, each partition member has a plurality of alignment holes that mate with a plurality of alignment projections (i.e., reference numeral 108) accommodated by the backplane 104. Each alignment projection (such as alignment projection 108) may be comprised of a plurality of substantially rigid materials, such as aluminum, steel, plastic, and so on. Furthermore, the alignment projections may comprise different form factors, such as a pin, a bolt, a nail, etc. Also, a screw fastener (i.e., a Phillips-head screw) can be used to couple the upper and lower partition members (reference numerals 103A and 103B) to the backplane through threaded alignment holes. In addition, the partition extension 102 can be coupled to the backplane 104 by various other means, such as removable rivets, clips, buckles, clasps, clamps, and so on, as alluded to hereinabove.

As set forth in the foregoing, the partition extension 102 may be horizontally disposed at a central location of the backplane 104, dividing a shelf into two separate compartments. When the partition extension is coupled to the backplane in this configuration, the shelf is capable of receiving a plurality of half-height line cards. If the partition extension is detached from the backplane, the same shelf is operable to receive a plurality of full-height line cards. Furthermore, where three or more banks of connector receptacles are provided, the partition extension 102 can be disposed at several other locations relative to the backplane 104, such as the upper one-third region, the upper one-quarter region, the lower one-third region, the lower one-quarter region, and so on, in order to allow the shelf to support line cards with a plurality of different form factors.

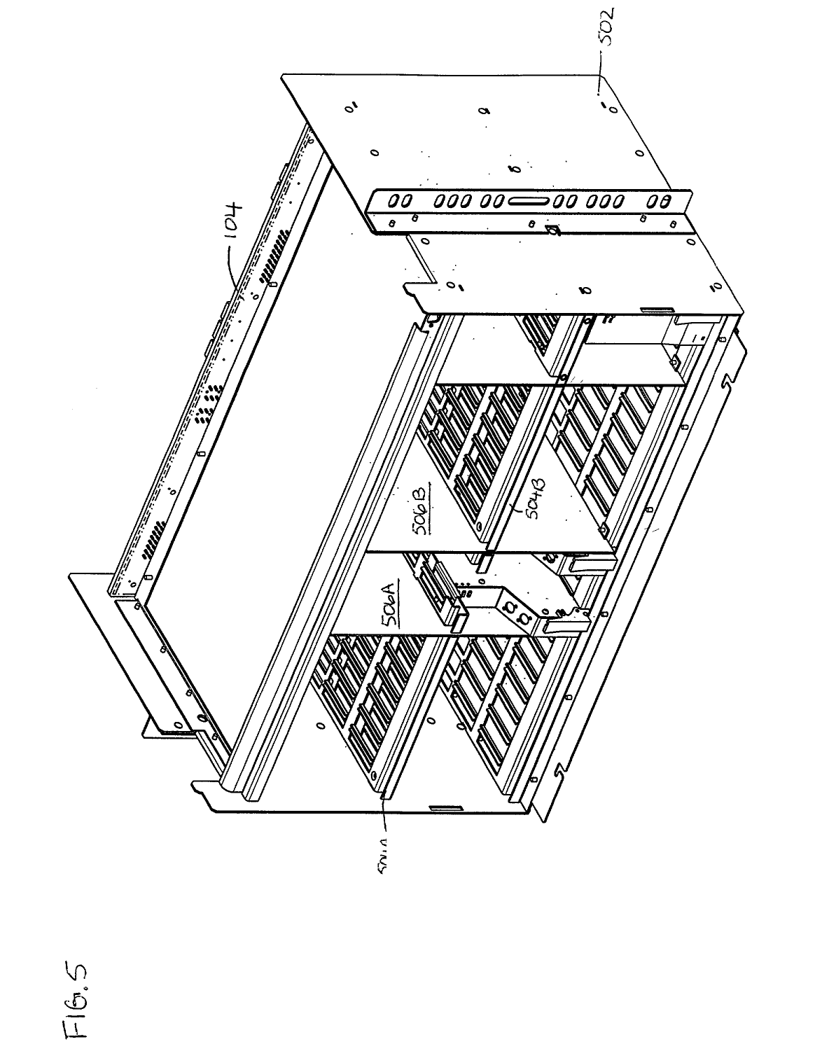

FIG. 5 depicts a perspective view of an exemplary embodiment of the present invention, wherein two detachable partition extensions (reference numerals 504A and 504B) are accommodated within a shelf 502. The shelf 502 accommodates two divider walls (reference numerals 506A and 506B) that are vertically disposed relative to the backplane 104 and separate the shelf 502 into two compartments. The shelf 502 is further compartmentalized into four quadrants when both partition extensions 504A and 504B are coupled to the back plane 104.

In the exemplary embodiment of the present invention shown in FIG. 5, both partition extensions 504A, 504B are co-planar and horizontally disposed relative to the backplane 104 at a mid-point between its top and bottom. As a result, the shelf 502 is operable to accommodate a plurality of half-height line cards in each of the four quadrants. If both the partition extensions 504A, 504B are detached from the backplane, the shelf is operable to receive a plurality of full-height line cards in each of the two compartments created by the two divider walls. When the first partition extension (i.e., partition extension 504B) is detached from the back plane 104 but the second partition extension (i.e., partition extension 504B) remains attached to the backplane 104, the shelf 502 is divided into three chambers comprising a half-shelf compartment and two quadrants. As a result, the half-shelf compartment can accommodate a plurality of full-height line cards, while the two quadrants can accommodate a plurality of half-height line cards.

Furthermore, the shelf 502 may be comprised of several different form factors, operable to support a plurality of partition extensions and a plurality of line cards possessing various types of card connectors. The backplane in that case may be provided with corresponding connector receptacles of different form factors. Accordingly, the partition extensions (i.e., partition extensions 504A or 504B) may have form factors that would enable the shelf 502 to simultaneously receive line cards of several different dimensions, e.g., full-height, half-height, quarter-height, and the like, even if only one partition extension is attached.

Based upon the foregoing Detailed Description, it should be readily apparent that the present invention provides an innovative solution for allowing the deployment of a single form factor shelf that can accommodate a plurality of line cards comprising different form factors (such as half-height line cards, full-height line cards, and so on) without the shortcomings and deficiencies of the conventional solutions set forth in the Background section of the present patent application.

The utilization of one or more detachable partition extensions in accordance herewith allows a shelf and ultimately a telecommunications system, for example, to be more flexible, modularizable, and cost efficient. Since line cards possessing a plurality of different form factors can be accommodated by a shelf that deploys a single form factor, a greater level of modularization in the equipment of a system (such as a telecommunications network) is realized. Furthermore, maintenance becomes highly efficient since fewer types of components are required for shelves deploying a single form factor.

Additionally, economies of scale can be realized when one or more detachable partition extensions are utilized in accordance with the teachings of the present invention. Because a shelf with a single form factor can advantageously accommodate line cards possessing a plurality of different form factors (i.e., half-height and full-height line cards) only one type of shelf needs to be deployed. As a result, the price of a shelf can be kept down by deploying them in volume.

It is believed that the operation and construction of the present invention will be apparent from the foregoing Detailed Description. While the exemplary embodiments of the apparatus shown and described have been characterized as being preferred, it should be readily understood that various changes and modifications could be made therein without departing from the scope of the present invention as set forth in the following claims. Accordingly, all such modifications, alterations, combinations, amendments, and the like should be deemed to be within the ambit of the present invention whose scope is defined solely by the claims set forth immediately hereinbelow.

What is claimed is:

1. A partition extension for compartmentalizing a shelf having a backplane, comprising:
an upper partition member having a front end portion and a back end portion; and
a lower partition member having a front end portion and a back end portion, wherein said back end portions of said upper and lower partition members are engaged together for coupling with said backplane at a predetermined location thereon such that said partition extension is substantially horizontally disposed relative to said backplane.

2. The partition extension for compartmentalizing a shelf as set forth in claim 1, wherein said upper partition member and said lower partition member are comprised of a substantially rigid material.

3. The partition extension for compartmentalizing a shelf as set forth in claim 2, wherein said substantially rigid material is comprised of metal.

4. The partition extension for compartmentalizing a shelf as set forth in claim 2, wherein said substantially rigid material is comprised of plastic.

5. The partition extension for compartmentalizing a shelf as set forth in claim 2, wherein said upper partition member and said lower partition member are detachable from said backplane.

6. The partition extension for compartmentalizing a shelf as set forth in claim 5, wherein said upper partition member and said lower partition member are coupled to said backplane at about half-way between said backplane's top and bottom.

7. The partition extension for compartmentalizing a shelf as set forth in claim 5, wherein said upper partition member and said lower partition member are coupled to said backplane at about one-third of the way from said backplane's top.

8. The partition extension for compartmentalizing a shelf as set forth in claim 5, wherein said upper partition member and said lower partition member are coupled to said backplane at about one-third of the way from said backplane's bottom.

9. The partition extension for compartmentalizing a shelf as set forth in claim 5, wherein said upper partition member and said lower partition member are coupled to said backplane at about one-quarter of the way from said backplane's top.

10. The partition extension for compartmentalizing a shelf as set forth in claim 5, wherein said upper partition member and said lower partition member are coupled to said backplane at about one-quarter of the way from said backplane's bottom.

11. The partition extension for compartmentalizing a shelf as set forth in claim 5, wherein said upper partition member and said lower partition member each incorporate a back flange that accommodates at least one alignment hole for coupling with at least one substantially rigid projection disposed on said backplane at said predetermined location.

12. The partition extension for compartmentalizing a shelf as set forth in claim 5, wherein said upper partition member and said lower partition member each incorporate a back flange for coupling with said backplane using coupler means selected from the group consisting of a screw fastener, a removable rivet, a clip, a buckle, a clasp, a clamp, a brace, a grip, a bolt, a lock, a nail, and a pin.

13. The partition extension for compartmentalizing a shelf as set forth in claim 5, wherein said upper partition member and said lower partition member accommodate a plurality of card guides.

14. The partition extension for compartmentalizing a shelf as set forth in claim 13, wherein said plurality of card guides comprises of 8 rows of card guides.

15. The partition extension for compartmentalizing a shelf as set forth in claim 13, wherein said plurality of card guides are formed of metal.

16. The partition extension for compartmentalizing a shelf as set forth in claim 13, wherein said plurality of card guides are formed of plastic.

17. A modularizable telecommunications equipment comprising:
a card cage assembly for housing a plurality of line cards having different form factors, said card cage assembly including a backplane for supporting a plurality of card connector receptacles that receive mating card connectors disposed on said line cards; and
at least one detachable partition extension operable to couple at a predetermined location on said backplane so as to compartmentalize said card cage assembly's interior space into a plurality of chambers, wherein said chambers are sized to accommodate different sizes of said line cards.

18. The modularizable telecommunications equipment as set forth in claim 17, wherein said card cage assembly is operable to house a plurality of full-height line cards when said at least one detachable partition extension is detached.

19. The modularizable telecommunications equipment as set forth in claim 18, wherein said at least one detachable partition extension is substantially horizontally disposed at about half-way between said backplane's top and bottom.

20. The modularizable telecommunications equipment as set forth in claim 19, wherein said card cage is operable to house a plurality of half-height line cards when said at least one detachable partition extension is coupled to said backplane.

21. The modularizable telecommunications equipment as set forth in claim 18, wherein said at least one detachable partition extension is substantially horizontally disposed at about one-third of the way from said backplane's top.

22. The modularizable telecommunications equipment as set forth in claim 18, wherein said at least one detachable partition extension is substantially horizontally disposed at about one-third of the way from said backplane's bottom.

23. The modularizable telecommunications equipment as set forth in claim 18, wherein said at least one detachable partition extension is substantially horizontally disposed at about one-quarter of the way from said backplane's top.

24. The modularizable telecommunications equipment as set forth in claim 18, wherein said at least one detachable partition extension is substantially horizontally disposed at about one-quarter of the way from said backplane's bottom.

25. The modularizable telecommunications equipment as set forth in claim 17, wherein said at least one partition extension is comprised of an upper partition member and a lower partition member.

26. The modularizable telecommunications equipment as set forth in claim 17, wherein said card cage assembly is operable to house a plurality of half-height line cards and a plurality of full-height line cards when said at least one detachable partition extension is coupled to said backplane at about half way between said backplane's top and bottom.
